(19) United States
(12) Patent Application Publication
(10) Pub. No.: US 2009/0283318 A1
(43) Pub. Date: Nov. 19, 2009

(54) Integrated EMI Shield Termination and Cable Support Apparatus

(75) Inventors: Wiclyff T. Bonga, Tampa, FL (US); Stephan H. Klein, Clearwater, FL (US); Scott A. Ishman, Siminole, FL (US)

Correspondence Address: HONEYWELL INTERNATIONAL INC.;PATENT SERVICES, 101 COLUMBIA ROAD, P O BOX 2245, MORRISTOWN, NJ, 07962-2245, US

(73) Assignee: HONEYWELL INTERNATIONAL INC., Morristown, NJ (US)

(21) Appl. No.: 12/120,003

(22) Filed: May 13, 2008

(51) Int. Cl. H05K 9/00

(52) U.S. Cl. 174/350; 361/818

(57) ABSTRACT

An Electro-Magnetic Interference (EMI) shield termination and support apparatus for a cable to be terminated at a printed wiring board (PWB) comprises a metal shield conductively attached to an EMI shield metallized area on a portion of the PWB. In a preferred embodiment, the shield comprises an EMI shield cap having a cable opening for receiving the cable to be terminated and a strain-relief feature to assist in providing strain relief to the cable soldered to the PWB. The combination of the shield and the metallized area provide EMI shielding to an end of the cable to be terminated. One cable or multiple cables may be terminated in accordance with described embodiments.

### GOVERNMENT RIGHTS

The United States government may have certain rights to this invention pursuant to government subcontract PP3-220014 from Lockheed Martin Corporation.

### FIELD

The present invention relates to physically supporting a cable and/or connector at a printed wiring board (PWB) and protecting such a supported cable and/or connector from electro-magnetic interference (EMI), and more particularly, to an integrated EMI shield termination and cable support apparatus.

### BACKGROUND

EMI shielding of electronic equipment has become increasingly important for product reliability, particularly for sensitive applications, such as electronics used in space (e.g. satellites and spaceflight computers). However, this shielding has become increasingly difficult to provide, due to the sheer multitude of cables and connectors present on today's electronics assemblies. Cables are frequently connected to a connector or directly soldered onto PWB pads, and therefore, must be properly shielded from EMI. In addition, the EMI shields themselves should be sufficiently terminated to reduce the risks of EMI leaks and to provide physical support for the cable and/or connector.

For cables or connectors directly soldered to a PWB, the solder joint is susceptible to breaking loose if subjected to loading, such as from vibration or other environmental impacts. In some space-based applications, g-loads of 50-100 g (or more) are now being observed, and in most of these applications, failures are generally not tolerated. Thus, a strain-relief feature for such an EMI shield would also be desirable.

### SUMMARY

An Electro-Magnetic Interference (EMI) shield termination and support apparatus for a cable to be terminated at a printed wiring board (PWB) comprises a metal shield conductively attached to an EMI shield metallized area on a portion of the PWB. In a preferred embodiment, the shield comprises an EMI shield cap having a cable opening for receiving the cable to be terminated and a strain-relief feature to assist in providing strain relief to the cable soldered to the PWB. The combination of the shield and the metallized area provide EMI shielding to an end of the cable to be terminated. One cable or multiple cables may be terminated in accordance with described embodiments.

### BRIEF DESCRIPTION OF THE DRAWINGS

FIG. 1 is a pictorial diagram illustrating alternate views A-C of a single-cable shield that may be used in an EMI shield termination and cable support apparatus, according to an embodiment of the present invention.

FIG. 2 is a pictorial diagram illustrating alternate installation views A-C of the single-cable shield of FIG. 1, with cable, that may be used in an EMI shield termination and cable support apparatus, according to an embodiment of the present invention.

FIG. 3 is a pictorial diagram illustrating perspective views A and B of a single-cable shield and multiple-cable shield, respectively, that may be used in an EMI shield termination and cable support apparatus, according to an embodiment of the present invention.

FIG. 4 is a pictorial diagram illustrating EMI shield termination and cable support apparatus embodiments in accordance with aspects of the present invention.

FIG. 5 is a partially exploded perspective diagram illustrating a multiple-cable shield with cable that may be used in an EMI shield termination and cable support apparatus, according to an embodiment of the present invention.

FIG. 6 is a pictorial diagram illustrating a plan view of a multiple-cable shield with cable that may be used in an EMI shield termination and cable support apparatus, according to an embodiment of the present invention.

### DETAILED DESCRIPTION OF PRESENTLY PREFERRED EMBODIMENTS

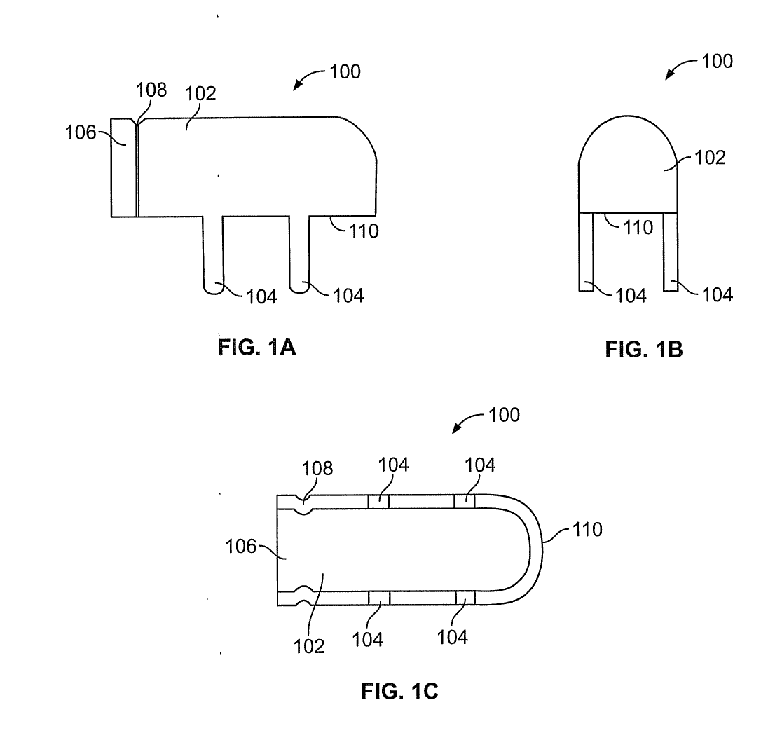

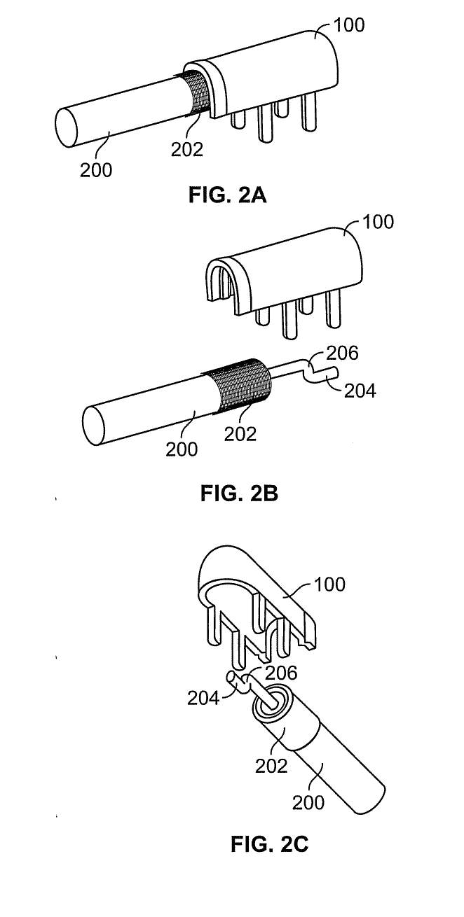

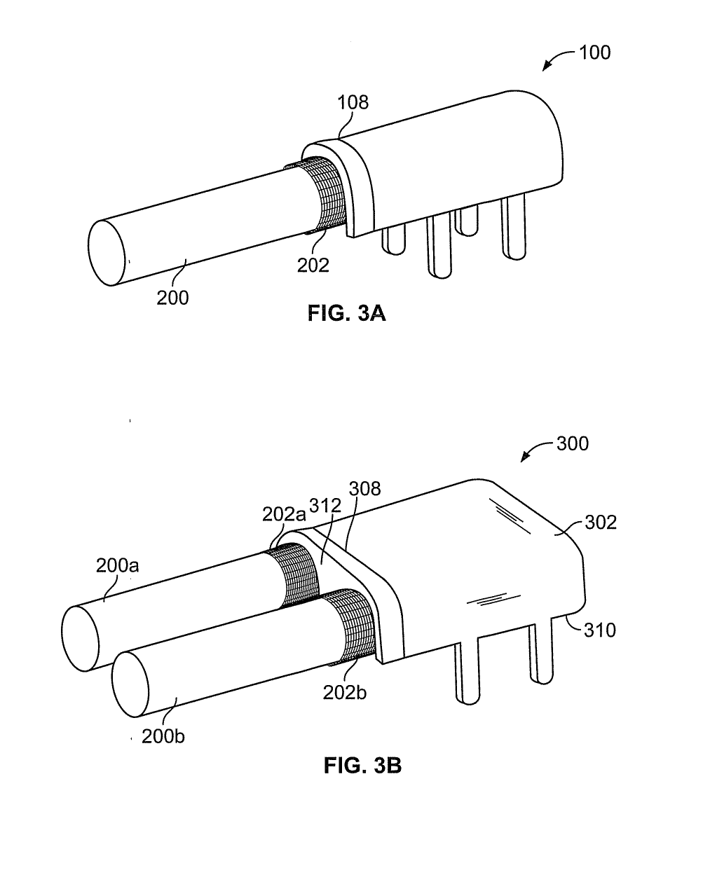

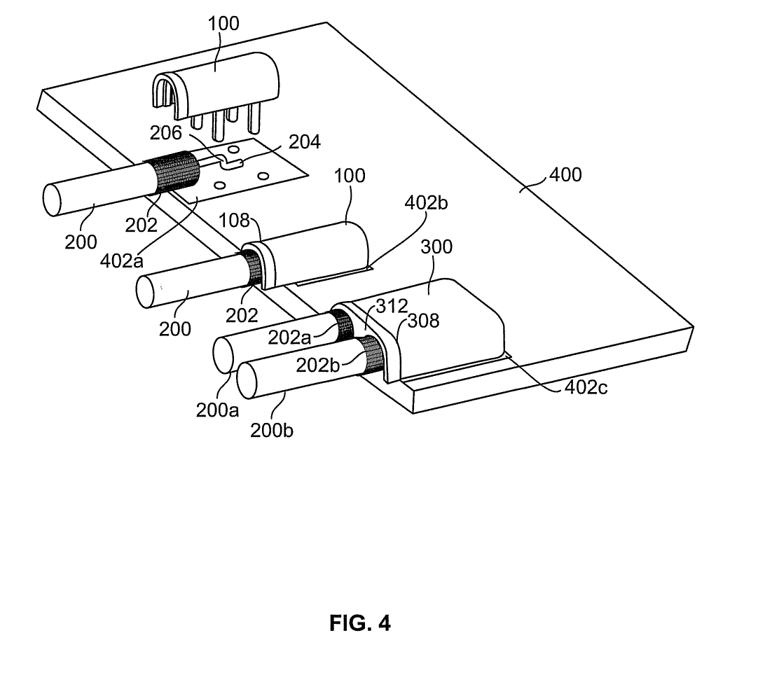

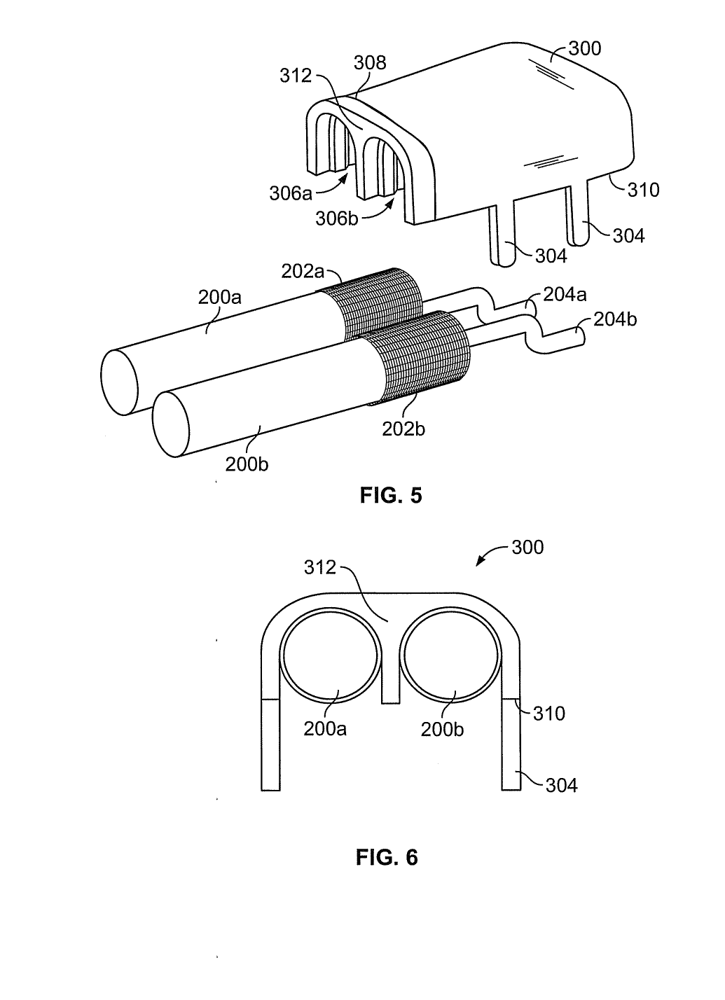

FIGS. 1-4 illustrate various views and configurations of a single-cable EMI shield termination and cable support apparatus, according to an embodiment of the present invention. In the figures and following description, consistent reference numbering refers to preferred components of the single-cable EMI shield termination and cable support apparatus across all figures. A second embodiment, relating to a multiple-cable EMI shield termination and cable support apparatus, will be described with reference to FIGS. 3-6 after the single-cable embodiment is set forth. For both embodiments described, the apparatus may be used to terminate a cable assembly (single or multiple cables) connecting connectors to solder pads on the printed wiring board. In the embodiments illustrated herein, details of PWB 400, such as solder pads, through-holes, components, and traces, are not shown in order to simply the illustrations to promote understanding of the salient features of the invention.

The single-cable EMI shield termination and cable support apparatus generally comprises a single-cable shield 100 in combination with an EMI shield metalized area 402a-b on a PWB 400. The shield 100 and EMI shield metalized area 402a-b preferably consist of one or more highly conductive materials, such as metals. For example, the shield 100 may be constructed from materials such as a beryllium copper alloy, a ferrous alloy, a nickel-cobalt ferrous alloy (such as Kovar, a registered trademark of Carpenter Technology Corporation, based in Wyomissing, Pa.), stainless steel, aluminum, or copper. Stainless steel, aluminum, and copper may be less preferable due to increased weight, decreased conductivity, and cost, respectively. The shield 100 can be manufactured using any of a number of manufacturing processes, including molding, machining, stamping, forming, or casting, for example. The EMI shield metalized area 402a-b, on the other hand, is preferably a nickel plated area or other highly conductive metallization on the PWB, which may be manufactured using processes such as those described above for the shield 100 (in combination with a mechanical fastening step) or metallic deposition processes. The EMI shield metalized area 402a-b may, for example, surround (without contacting) a solder pad to which a cable or cable connector may be soldered.

The particular application in which the apparatus is employed will dictate which material will be most suitable. In many applications, the desired attributes (in addition to EMI protection and physical support) for the shield 100 will be to keep moisture out and prevent corrosion in a cost and weight-effective manner. In addition to providing EMI shielding, the EMI shield metalized area 402a-b should conform to the surface of the PWB (or other mounting surface, such as a riser) and have lateral dimensions approximating that of the footprint of the shield 100. The combination of the shield 100 and EMI shield metalized area 402a-b effectively forms an EMI isolation box around the end of a cable or connector to be terminated.

The shield 100 includes an EMI shield cap 102 having a cable opening 106 and a shape substantially conforming to the general shape of the end of a cable 200 to be terminated, with interior cavity dimensions allowing the end of the cable 200 to fit inside the EMI shield cap 102. A mounting mechanism, such as a plurality of through-hole mounting pegs 104, may be used to secure the shield 100 to the PWB 400, in order to bring the interface surface 110 of the shield 100 adjacent to the EMI shield metalized area 402a-b. During installation, the through-hole mounting pegs 104 may be placed through through-holes (not shown) on the PWB and then soldered and trimmed or bent to secure the shield 100 (and cable/connector) to the PWB. As an alternative to through-hole mounting pegs, the shield 100 may be mounted to the PWB using Surface-Mount Technology (SMT) incorporating solder reflow or other methods of attachment.

Through-hole mounting may be preferred in certain embodiments where heavy vibrations or g-forces are to be subjected to the PWB and cable/connector assembly. The mounting technique and shape of the shield interface surface 110 with respect to the EMI shield metalized area 402a-b preferably results in substantially no gap between the interface surface 110 and the EMI shield metallized area 402a-b. The entire perimeter of the interface surface 110 (or a portion thereof) may be soldered to the EMI shield metalized area 402a-b to close the gap and/or to provide additional holding force. Solder tabs may be used if only a portion of the interface surface 110 is soldered to the EMI shield metallized area. As an alternative to solder, other bonding techniques, such as those using epoxy (e.g. conductive epoxy or metal-impregnated epoxy), may be used.

In order to facilitate physically supporting the cable 200 to be soldered to the PWB 400, the shield 100 includes a strain-relief feature 108 adjacent to the cable opening 106. The strain-relief feature 108 assists in providing strain relief to the cable 200 just soldered to the PWB 400, in order to promote solder joint reliability. In addition, the strain-relief feature 106 can provide strain relief functionality while the PWB 400 and cable/connector assembly is being used in its intended application. In the application shown, the cable comprises a single cable wire 204 with an interface bend 206 to bring the end of the cable wire 204 in communication with the PWB 400 or other contact surface for soldering or other electrical connection. The cable wire 204 may comprise multiple wires (e.g. a twisted pair) in some embodiments.

If the cable 200 is a shielded cable (as shown) comprising a cable wire inner shield 202 that is folded back around the end of the cable or is a slip-on mesh cover, the strain relief feature 108 can penetrate into and/or contact the inner shield. The strain-relief feature 108 is essentially a bottleneck in the shield 100 that subjects a holding force to the cable 200 so that the solder joint is not wholly responsible for securing the cable 200 to the PWB 400. The strain-relief feature 108 may take the form of an interior lip molded or stamped into the shield 100, for example. Alternatively, the strain-relief feature 108 may be a back-shell clamp or a separate piece of material press-fit into the shield 100 (such as in an internal slot in the shield 100), which would provide some degree of adjustability for different cable sizes. As another alternative, the shield 100 could include a weakened part that would crimp inward when subjected to the force of a tool, such as a pliers or clamp. As yet another alternative, solder could be wicked into the interface between the shield 100 and cable 200 once the cable is inserted. Once cooled, the solder would assist in providing strain relief. The strain relief feature 108 is preferably made of a highly conductive material, such as the same material as the shield cap 102.

FIGS. 3-6 illustrate various views and configurations of a multiple-cable EMI shield termination and cable support apparatus, according to an embodiment of the present invention. The multiple-cable EMI shield termination and cable support apparatus is similar to the single-cable EMI shield termination and cable support apparatus described above except that it is designed to shield more than one cable. The illustrated embodiment is designed for two-cable EMI shielding; however, these same concepts (and those described above with reference to the single-cable embodiment) are applicable for other numbers of cables to be terminated.

The multiple-cable EMI shield termination and cable support apparatus generally comprises a multiple-cable shield 300 in combination with an EMI shield metalized area 402c on the PWB 400. The multiple-cable shield 300 is similar to the single-cable shield 100, with an EMI shield cap 302 and through-hole mounting pegs 304 (or other mounting mechanism). However, in addition, the multiple-cable shield 300 includes a plurality of cable openings 302a-b corresponding to the number of cables 200a-b to be terminated. An interior shield 312 may be included where the cables 200a-b enter the EMI shield cap 302 and between the cables 200a-b if shielding between the cables is desired or required. The interior shield 312 may extend downward from the top of the EMI shield cap 302 to be even with a lower circumferential edge of the shield cap 302 to collectively form an interface surface 310 to be bonded to the PWB 400 (such as on the metalized area 402c).

Similarly, the shield 300 may include a strain relief feature 308 similar to what was described above with reference to the single-cable shield 100. In a preferred embodiment, the strain relief feature 308 at least partially surrounds each of the plurality of cables 200a-b individually. In alternative embodiment, the strain relief feature 308 could surround the plurality of cables 200a-b collectively (such as in a case where no interior shield 312 is included), but the strain relief capabilities would likely be reduced in such a configuration.

Various arrangements and embodiments in accordance with the present invention have been described herein. It will be appreciated, however, that those skilled in the art will understand that changes and modifications may be made to these arrangements and embodiments as well as combination of the various embodiments without departing from the true scope and spirit of the invention, which is defined by the following claims.

We claim:

1. An Electro-Magnetic Interference (EMI) shield termination and support apparatus for a cable to be terminated at a printed wiring board (PWB), comprising:
a shield comprising
an EMI shield cap,
a mounting mechanism for mounting the shield to the PWB,
a cable opening for receiving the cable to be terminated, and
an interface surface for interfacing the shield to the PWB; and
an EMI shield metallized area on a portion of the PWB, wherein the shield is mounted to the PWB so that substantially no gap exists between the interface surface and the EMI shield metallized area, whereby the combination of the shield and the metalized area provide EMI shielding to an end of the cable to be terminated.

2. The apparatus of claim 1, wherein the shield further comprises a strain-relief feature.

3. The apparatus of claim 1, wherein the strain-relief feature comprises a bottleneck in the shield that subjects a holding force to the cable.

4. The apparatus of claim 1, wherein the strain-relief feature is an integral part of the EMI shield cap.

5. The apparatus of claim 1, wherein the strain-relief feature is a separate part from the EMI shield cap.

6. The apparatus of claim 1, wherein the strain-relief feature is a weakened portion of the EMI shield cap that may be indented by application of a tool to the EMI shield cap.

7. The apparatus of claim 1, wherein the EMI shield cap is manufactured from a metal.

8. The apparatus of claim 1, wherein the EMI shield cap is manufactured from a highly conductive material from the group consisting of beryllium copper alloy, a ferrous alloy, a nickel-cobalt ferrous alloy, stainless steel, aluminum, or copper.

8. The apparatus of claim 1, wherein the EMI shield metalized area is a nickel plated area.

9. The apparatus of claim 8, wherein the nickel plated area surrounds a solder pad to which a wire in the cable is soldered.

10. The apparatus of claim 1, wherein the mounting mechanism comprises a plurality of through-hole pegs that may be placed into a corresponding plurality of through-holes in the PWB.

11. The apparatus of claim 1, wherein the mounting mechanism comprises Surface Mount Technology (SMT).

12. The apparatus of claim 1, wherein the interface surface is adhered to the EMI shield metallized area.

13. The apparatus of claim 12, wherein the interface surface is soldered to the EMI shield metallized area.

14. The apparatus of claim 12, wherein the interface surface is adhered to the EMI shield metallized area with epoxy.

15. The apparatus of claim 1, wherein the shield further comprises a second cable opening for receiving a second cable to be terminated.

16. The apparatus of claim 15, wherein the shield further comprises a cable opening interior shield configured to provide EMI shielding between the cable and the second cable.

17. An Electro-Magnetic Interference (EMI) shield termination and support apparatus for a cable to be terminated at a printed wiring board (PWB), comprising a metal shield conductively attached to an EMI shield metallized area on a portion of the PWB, wherein the shield comprises an EMI shield cap having a cable opening for receiving the cable to be terminated and a strain-relief feature to assist in providing strain relief to the cable soldered to the PWB, whereby the combination of the shield and the metallized area provide EMI shielding to an end of the cable to be terminated.

18. The apparatus of claim 17, wherein the cable is a shielded cable comprising a cable wire inner shield, and wherein the strain-relief feature makes contact with the cable wire inner shield when the cable is installed.

19. An Electro-Magnetic Interference (EMI) shield termination and support apparatus for terminating a plurality of cables at a printed wiring board (PWB), comprising a metal shield conductively attached to an EMI shield metallized area on a portion of the PWB, wherein the shield comprises an EMI shield cap having a plurality of cable openings for receiving the plurality of cables to be terminated and a strain-relief feature to assist in providing strain relief to the plurality of cables.

20. The apparatus of claim 19, further comprising a cable opening interior shield.
